(19) United States
(12) Patent Application Publication
(10) Pub. No.: US 2023/0374346 A1
(43) Pub. Date: Nov. 23, 2023

(54) SURFACE-MODIFIED SILICA PARTICLES AND COMPOSITIONS COMPRISING SUCH PARTICLES

(71) Applicant: MERCK PATENT GMBH, DARMSTADT (DE)

(72) Inventor: Eric JACQUINOT, Trosly Breuil (FR)

(73) Assignee: MERCK PATENT GMBH, DARMSTADT (DE)

(21) Appl. No.: 18/027,720

(22) PCT Filed: Sep. 21, 2021
(86) PCT No.: PCT/EP2021/075868

§ 371 Date: Mar. 22, 2023

(30) Foreign Application Priority Data
Sep. 23, 2020 (EP) 20306085.0

(51) Int. Cl. C09G 1/02; C01B 33/149

(52) U.S. Cl. CPC C09G 1/02; C01B 33/149

(57) ABSTRACT

The present invention relates to surface-modified silica particles comprising an alkoxy organosilane and to compositions comprising such particles as well as to uses of such surface-modified silica particles and compositions comprising such particles.

### TECHNICAL FIELD

The present invention relates to surface-modified silica particles comprising an alkoxy organosilane and to compositions comprising such particles as well as to uses of such surface-modified silica particles and compositions comprising such particles.

### BACKGROUND

Modern semiconductor devices, memory devices, integrated circuits, and the likes comprise alternating layers of conductive layers, semiconductive layers, and dielectric (or insulating) layers, with the dielectric layers insulating the conductive layers from one another. Connections between conductive layers may be established, for example, by metal vias. In producing such devices conductive, semiconductive, and/or dielectric materials are consecutively deposited onto and in part again removed from the surface of a semiconductive wafer.

With such devices becoming smaller and smaller the accuracy of deposition and the thickness of the various layers becomes ever more important for ensuring that the so-produced devices perform according to expectation. It is therefore important to have planar surfaces, onto which a subsequent layer is to be deposited. As the required planarity cannot be achieved by deposition, the wafer (respectively, the device to be produced) needs to be planarized by removing part or in some instances even all of such layer.

Chemical-mechanical polishing (CMP) is a widely used method for planarizing or removing part or all of a layer in the process of producing semiconductor devices and the likes. In the CMP process, an abrasive and/or corrosive chemical slurry, such as for example a slurry of silica particles, is used together with a polishing pad. Pad and substrate or surface, e.g. a wafer, are pressed together and generally rotated non-concentrically, i.e. with different rotational axes, thereby abrading and removing material from the surface or substrate.

CMP may be used to polish a wide range of materials, such as metals or metal alloys (such as, for example, aluminum, copper or tungsten), metal oxides, silicon dioxide, or even polymeric materials. For each material, the polishing slurry needs to be specifically formulated so as to optimize its performance. For example, if a tungsten layer that has been deposited onto a silicon dioxide layer is to be polished, the polishing slurry preferably has a high removal rate for tungsten but a lower one for silicon dioxide so as to efficiently remove the tungsten but leave the silicon dioxide layer largely intact.

Further, because the polishing preferably is done by a combination of mechanical polishing and chemical corrosion, the silica particles need to fulfill certain requirements so as to be fully compatible with the formulation. For example, the composition of the silica particles needs to be modified depending upon whether the particles are to be anionic or cationic.

However, for improved efficiency of the production process there is still a need in industry to provide silica particles allowing for good selectivity between conductive and/or semiconductive materials on the one hand, and dielectric materials on the other hand.

Thus, the present application aims at providing silica particles and compositions comprising such silica particles allowing for good selectivity between one or more conductive layer, which may comprise any one or more of metal, metal alloy, polysilicon, and any other suitable material, and one or more dielectric layer, preferably in such a way that the removal rate for dielectric materials is significantly lower than for metals and metal alloys, particularly tungsten.

US 2020/0239737 A1 discloses a chemical mechanical polishing composition comprising water, colloidal silica abrasive particles and a polyalkoxy organosilane, the chemical mechanical polishing composition having a pH>7.

### SUMMARY

The present inventors have now surprisingly found that the above objects may be attained either individually or in any combination by the present surface-modified silica particles and compositions.

The present application therefore provides for modified silica particles comprising an alkoxy organosilane on the surface.

Additionally, the present application provides for a composition comprising water and such modified silica particles, wherein the composition is acidic.

The present application also provides for a method for producing such modified silica particles, said method comprising the steps of
(a) providing an aqueous dispersion of silica particles;
(b) providing an alkoxy organosilane;
(c) in case said aqueous dispersion not yet being acidic, subsequently rendering the aqueous dispersion of silica particles acidic; and
(d) then bringing the silica particles and the alkoxy organosilane into contact with each other, thereby obtaining the modified silica particles.

Furthermore, the present application provides for a method for chemical mechanical polishing comprising the steps of
(A) providing a substrate comprising
   (i) at least one layer comprising, preferably essentially consisting of, silicon oxide; and
   (ii) at least one layer comprising, preferably essentially consisting of, one or more metal or metal alloy;
(B) providing said composition;
(C) providing a chemical mechanical polishing pad with a polishing surface;
(D) bringing the polishing surface of the chemical mechanical polishing pad into contact with the substrate; and
(E) polishing the substrate such that at least a part of the substrate is removed.

### DETAILED DESCRIPTION

Throughout this application, “Me” denotes a methyl group (CH₃), and “Et” denotes an ethyl group (CH₂-CH₃).

In the present application, the term “point of use” denotes the chemical mechanical polishing (CMP) process. For example, the expression “composition at point of use” is used to denote the composition as used in the chemical mechanical polishing (CMP) process.

The present application relates to modified silica particles, more specifically to surface-modified silica particles, comprising an alkoxy organosilane on the surface, and their method of production, as well as to a composition comprising such modified silica particles, and a method of chemical-mechanical polishing with such composition.

It is noted that throughout this application the terms “modified silica particles” and “surface-modified silica particles” may be used interchangeably.

The surface-modified silica particles are produced by bringing (unmodified) silica particles, in the following simply referred to as “silica particles”, into contact with one or more alkoxy organosilane. Without wishing to be bound by theory it is believed that under the conditions used herein and described in the following, this will result in the alkoxy organosilane becoming covalently bound to the surface of the silica particles, thus yielding the present surface-modified silica particles. Such reaction and the alkoxy organosilane being bound to the surface of such surface-modified silica particle may without wishing to be bound by theory, for example, be represented as follows:

R^{a}—Si(—O—R^{b})₃+HO—Si—X→R^{a}—Si(—O—R^{b}₂—S—Si—X+R^{b}—OH (eq. I)

with R^{a} being an alkoxy group covalently bound to Si by an alkanediyl group; R^{b} being an organyl group, for example, an alkyl group; and X representing the silica particle. Alternatively, two or even all three R^{b}O-groups of the alkoxy organosilane may react in this manner with hydroxyl group on the surface of the silica particle

For the purposes of the present application the choice of silica particles is not particularly limited. The silica particles used herein may, for example, be any type of colloidal silica particles. The present silica particles may have been produced from any suitable starting material, and may, for example, be water glass-based or TMOS/TEOS-based.

As used herein, the term “water glass” is used to generally denote alkali salts, preferably sodium and potassium salts, of silicic acid Si(OH)₄. The respective sodium and potassium salts may, for example, be represented by the formula M₂ₓSi_{y}O_{2y+x} or (M₂O)ₓ·(SiO₂)_{y}, with M=Na or K and, for example, x=1 and y being an integer of from 2 to 4.

As used herein, the term “water glass-based” is used to denote that the present silica particles are preferably produced from such alkali salts of silicic acid as starting material.

As used herein, the term “TMOS/TEOS-based” is used to generally denote silica particles that have been produced using Si(OMe)₄ (“TMOS”) and/or Si(OEt)₄ (“TEOS”) as starting material.

Generally, the silica particles as used herein may be obtained in a wet process from above described starting materials as is well known to the person skilled in the art and, for example, disclosed in R. K. Iler, “The Chemistry of Silica: Solubility, Polymerization, Colloid and Surface Properties and Biochemistry of Silica”, Wiley, 1979. For producing the present silica particles comprised in the present silica slurry, it is preferred that the silica particles are obtained in a wet process from an alkaline silicate.

Though generally all types of silica particles may be used herein, it is nevertheless preferred that the silica particles used herein and particularly the present modified silica particles are anionic, i.e. carry a permanent negative charge.

Shape and dimensions of the silica particles used herein are not particularly limited, provided that such silica particles are suitable for use in CMP applications. Such silica particles may, for example, be spherical, oval, curved, bent, elongated, branched, or cocoon-shaped.

For spherical silica particles, the average diameter is preferably at least 5 nm, more preferably at least 10 nm, and most preferably at least 15 nm. For spherical particles, the average diameter is preferably at most 200 nm, more preferably at most 150 nm or 100 nm, even more preferably at most 90 nm or 80 nm or 70 nm or 60 nm, still even more preferably at most 50 nm or 45 nm or 40 nm or 35 nm or 30 nm, and most preferably at most 25 nm. For example, particularly preferred silica particles have an average diameter of at least 15 nm and of at most 25 nm.

For elongated, curved, bent, branched, and oval silica particles their average diameter is preferably as described above for spherical colloidal silica particles. Preferably, such elongated or oval colloidal silica particles have an aspect ratio, i.e. the ratio of length to average diameter, of at least 1.1, more preferably of at least 1.2 or 1.3 or 1.4 or 1.5, even more preferably at least 1.6 or 1.7 or 1.8 or 1.9, and most preferably at least 2.0. Said aspect ratio is preferably at most 10, more preferably at most 9 or 8 or 7 or 6, and most preferably at most 5.

The alkoxy organosilane used herein is preferably hydrophilic.

The alkoxy organosilane used herein preferably is a poly(alkoxy) organosilane. More preferably, said alkoxy organosilane is of the following formula (I)

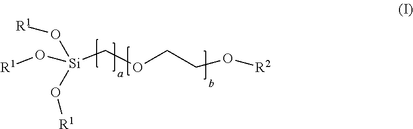

wherein
R¹ and R² are at each occurrence independently of each other selected from the group consisting of methyl, ethyl and propyl;
a is an integer of at least 1 and at most 5; and
b is an integer of at least 1 and at most 30, preferably at most 25, and even more preferably at most 20.

Preferred examples of alkoxy organosilanes of formula (I) are those, wherein R¹ and R² are all Me or Et, a is 3, and b is at least 6 and at most 12. For example, b may be at least 6 and at most 9, or at least 9 and at most 12, or at least 8 and at most 12.

Most preferably, the alkoxy organosilane used herein is one of formula (I), wherein R¹ and R² are all methyl, a is 3, and b is 11.

Such alkoxy organosilanes may, for example, be obtained from Momentive Performance Materials, Albany, NY, USA.

Preferably, the alkoxy organosilane as defined herein is reacted with the present silica particles in a weight ratio of alkoxy organosilane to silica particles of at least 0.001, more preferably of at least 0.005, even more preferably of at least 0.010, still even more preferably of at least 0.015, and most preferably of at least 0.020.

Preferably, the alkoxy organosilane as defined herein is reacted with the present silica particles in a weight ratio of alkoxy organosilane to silica particles of at most 0.50, more preferably of at most 0.40 or 0.30, even more preferably of at most 0.20, still even more preferably of at most 0.15 or 0.10, and most preferably of at most 0.050.

Preferably, the present silica particles are doped by bringing them into contact with an aluminate, more preferably with an alkali metal aluminate (M[Al(OH)₄] with M being an alkali metal). Preferred examples of such alkali metal aluminate are sodium aluminate or potassium aluminate, with sodium aluminate being most preferred.

Preferably, the doping of the silica particles as used herein with such aluminate results in the such doped silica particles comprising at least 10 ppm, more preferably at least 20 ppm or 30 ppm or 40 ppm or 50 ppm, even more preferably at least 60 ppm or 70 ppm, still even more preferably at least 80 ppm or 90 ppm, and most preferably at least 100 ppm of aluminum, with ppm relative to the weight of the doped silica particle.

Preferably, the doping of the silica particles as used herein with such aluminate results in such doped silica particles comprising at most 1000 ppm, more preferably at most 900 ppm or 800 ppm or 700 ppm, even more preferably at most 600 ppm or 500 ppm, and most preferably at most 400 ppm of aluminum, with ppm relative to the weight of the doped silica particle.

The present modified silica particles may be produced by a process comprising the steps of
(a) providing an aqueous dispersion of silica particles as defined above, and
(b) providing an alkoxy organosilane as defined above.

In the present method it is necessary that the aqueous dispersion of the silica particles is acidic. Preferably, said aqueous dispersion has a pH of at least 1.0, more preferably of at least 2.0. Preferably, said aqueous dispersion has a pH of at most 5.0, more preferably of at most 4.0.

Thus, the present method also comprises the step of
(c) rendering the aqueous dispersion of silica particles acidic if it is not already acidic, and preferably adjusting the pH to a range as indicated above for the aqueous dispersion of silica particles.

In the following the now acidic aqueous dispersion of silica particles and the alkoxy organosilane as defined earlier are brought into contact with each other, thereby obtaining the modified silica particles. This may be done simply by mixing the acidic aqueous dispersion of silica particles and the alkoxy organosilane, and optionally stirring for a certain amount of time, possibly at elevated temperatures.

Thus, the present method comprises the step of
(d) then bringing the silica particles and the alkoxy organosilane into contact with each other, thereby obtaining the modified silica particles.

Optionally, the silica particles comprised in said aqueous dispersion may be doped with an aluminate as described above, such doping being preferably performed following step (a) but before step (c).

The present surface-modified silica particles may be used in a composition, the composition further comprising water. Thus, such composition comprises the present surface-modified silica particles and water. The water is preferably deionized water.

The present composition comprising water and the above-described modified silica particles is acidic, i.e. is characterized by an acidic pH. The present composition preferably has a pH of at least 1.0, more preferably of at least 2.0. The present composition preferably has a pH of at most 5.0, more preferably of at most 4.0.

If supplied as a concentrate, which may then be diluted with water, preferably deionized water, prior to its use in a chemical mechanical polishing process, the present composition may comprise the modified silica particles in up to 20 wt %, preferably in up to 25 wt %, more preferably in up to 30 wt %, even more preferably in up to 35 wt %, still even more preferably in up to 40 wt % and most preferably in up to 50 wt %, with wt % relative to the total weight of the present composition.

Alternatively, at the point of use, i.e. when used in a chemical mechanical polishing process, the present composition preferably comprises the modified silica particles in at least 0.1 wt % (for example in at least 0.2 wt % or 0.3 wt % or 0.4 wt %), more preferably in at least 0.5 wt %, even more preferably in at least 1.0 wt, still even more preferably in at least 1.5 wt %, and most preferably in at least 2.0 wt %, with wt % relative to the total weight of the present composition. In this case, the present composition preferably comprises the modified silica particles in at most 10 wt %, more preferably in at most 5.0 wt %, even more preferably in at most 4.0 wt %, still even more preferably in at most 3.5 wt %, and most preferably in at most 3.0 wt %, with wt % relative to the total weight of the present composition.

Optionally, the present composition further comprises any one or more of the group consisting of biocide, pH-adjusting agent, pH-buffering agent, oxidizing agent, chelating agent, corrosion inhibitor, and surfactant.

Such oxidizing agent may be any suitable oxidizing agent for the one or more metal or metal alloy of the substrate to be polished using the present composition. For example, the oxidizing agent may be selected from the group consisting of bromates, bromites, chlorates, chlorites, hydrogen peroxide, hypochlorites, iodates, monoperoxy sulfate, monoperoxy sulfite, monoperoxy phosphate, monoperoxy hypophosphate, monoperoxy pyrophosphate, organo-halo-oxy compounds, periodates, permanganate, peroxyacetic acid, ferric nitrates, and any blend of any of these. Such oxidizing agent may be added to the present composition in a suitable amount, for example, in at least 0.1 wt % and at most 6.0 wt %, with wt % relative to the total weight of the present composition at point of use.

Such corrosion inhibitor, which may, for example, be a film forming agent, may be any suitable corrosion inhibitor. For example, the corrosion inhibitor may be glycine, which may be added in an amount of at least 0.001 wt % to 3.0 wt %, with wt % relative to the total weight of the present composition at point of use.

Such chelating agent may be any suitable chelating or complexing agent for increasing the removal rate of the respective materials, preferably metal or metal alloy, to be removed, or alternatively or in combination for capturing trace metal contaminants that may unfavorably influence performance in the polishing process or in the finished device. For example, the chelating agent may be compounds comprising one or more functional groups comprising oxygen (such as carbonyl groups, carboxyl groups, hydroxyl groups) or nitrogen (such as amine groups or nitrates). Examples of suitable chelating agents include, in a non-limiting way, acetylacetonates, acetates, aryl carboxylates, glycolates, lactates, gluconates, gallic acid, oxalates, phthalates, citrates, succinates, tartrates, malates, ethylenediaminetetraacetic acid and salts thereof, ethylene glycol, pyrogallol, phosphonates, ammonia, amino alcohols, di- and tri-amines, nitrates (e.g. ferric nitrates), and any blend of any of these.

Such biocide may be selected from any suitable biocide, for example, from isothiazolin derivative-comprising biocides. Such biocide is generally added in an amount of at least 1 ppm and of at most 100 ppm, with ppm relative to the total weight of the present composition at point of use. The amount of biocide added may be adapted depending, for example, upon the composition and planned storage period.

Such pH-adjusting agent may be selected from suitable acids, such as hydrochloric acid, nitric acid or sulfuric acid, with nitric acid or sulfuric acid being preferred, and with nitric acid being particularly preferred.

Such surfactant may be selected from any suitable surfactant, such as cationic, anionic and non-ionic surfactants. A particularly preferred example is an ethylenediamine polyoxyethylene surfactant. Generally, surfactants may be added in an amount of from 100 ppm to 1 wt %, with ppm and wt % relative to the total weight of the present composition at point of use.

Some of these compounds may exist in form of a salt, such as a metal salt, acid, or as a partial salt. Equally, some of these compounds may fulfill more than one function if comprised in a composition suitable for chemical mechanical polishing. For example, ferric nitrates, particularly Fe(NO₃)₃, may act as chelating agent and/or oxidizing agent and/or catalyst agent.

A particularly preferred example of a composition at point of use that may be used herein comprises
(i) at least 1.0 wt % and at most 4.0 wt % of surface-modified silica particles as defined herein,
(ii) at least 0.001 wt % and at most 0.10 wt %, preferably at least 0.01 wt % and at most 0.05 wt % of Fe(NO₃)₃,
(iii) at least 10 ppm and at most 100 ppm of Kathon ICP II biocide,
(iv) optionally at least 0.01 wt % and at most 0.05 wt % of ma Ionic acid,
(v) at least 1.0 wt % and at most 8.0 wt % of hydrogen peroxide (H₂O₂), and
(vi) water in such an amount to bring the total up to 100 wt %, with ppm and wt % relative to the total weight of the composition at point of use.

The present composition may be prepared by standard methods, well known to the person skilled in the art. Generally such preparation involves mixing and stirring phases. It can be performed either in continuous manner or batchwise.

The composition as described above may be used in a chemical mechanical polishing (CMP) process, wherein a substrate is polished. The substrate to be polished in the present CMP process comprises (i) at least one layer comprising, preferably essentially consisting of, silicon oxide, and (ii) at least one layer comprising, preferably essentially consisting of one or more metal or metal alloy. The present method for chemical mechanical polishing therefore comprises the following steps of
(A) providing a substrate comprising (i) at least one layer comprising, preferably essentially consisting of, silicon oxide; and, preferably thereon, (ii) at least one layer comprising, preferably essentially consisting of, one or more metal or metal alloy; and
(B) providing the composition as defined herein.

As used herein, the term “thereon” is used to indicate that the metal or metal alloy-comprising layer is essentially placed/located on top of the silicon oxide-comprising layer. Expressed differently, and with respect to the chemical mechanical polishing, the layer on top is the layer that before starting to polish is in closer proximity to the polishing pad mounted on the CMP polisher.

As used herein, the term “essentially consisting of” is used to denote that such layer may comprise a minor amount of a different material, for example, in an amount of at most 5 wt % (for example in an amount of at most 4 wt % or 3 wt % or 2 wt % or 1 wt % or 0.5 wt % or 0.1 wt %), with wt % relative to the total weight of such layer.

Preferably, said silicon oxide comprised in the layer, which is in turn comprised in the substrate, may be selected from the group consisting of borophosphosilicate glass (BPSG), plasma-enhanced tetraethyl ortho silicate (PETEOS), thermal oxide, undoped silicate glass, high density plasma (HDP) oxide, and silane oxide.

Preferably, said metal or metal alloy comprised in the layer, which is in turn comprised in the substrate, may be selected from the group consisting of tungsten, tantalum, copper, titanium, titanium nitride, aluminum silicon, and any combination of any of these, and preferably is tungsten.

In the CMP-process a polishing pad with a polishing surface is used for the actual polishing of the substrate. Such polishing pad may, for example, be a woven or non-woven polishing pad, and comprise or essentially consist of a suitable polymer. Exemplary polymers include polyvinylchloride, polyvinylfluoride, nylon, poly-propylene, polyurethane, and any blend of these, to only name a few. Polishing pad and the to be polished substrate are generally mounted on a polishing apparatus, pressed together, and generally rotated non-concentrically, i.e. with different rotational axes, thereby abrading and removing material from the surface or substrate. Thus, the present CMP process further comprises the steps of
(C) providing a chemical mechanical polishing pad with a polishing surface;
(D) bringing the polishing surface of the chemical mechanical polishing pad into contact with the substrate; and
(E) polishing the substrate such that at least a part of the substrate is removed.

The present CMP process may be applied in the production of flat panel displays, integrated circuits (ICs), memory or rigid disks, metals, interlayer dielectric devices (ILDs), semiconductors, micro-electro-mechanical systems, ferroelectrics, and magnetic heads. In other words, the substrate to be polished in the present CMP process may be selected from the group consisting of flat panel displays, integrated circuits (ICs), memory or rigid disks, metals, interlayer dielectric devices (ILDs), semiconductors, micro-electro-mechanical systems, ferroelectrics, and magnetic heads.

### EXAMPLES

All of the materials used in the examples are commercially available. Sodium aluminate, malonic acid and iron nitrate (Fe(NO₃)₃) may, for example, be obtained from SigmaAldrich. The alkoxy silane, Silquest A-1230, was obtained from Momentive Performance Materials, Albany, NY, USA. Kathon ICP II biocide was obtained from DuPont de Nemours, Wilmington, Delaware, USA. Water glass-based silica particles were obtained internally from Merck KGaA, Darmstadt, Germany, and are commercially marketed under the Klebosol® tradename.

Examples were conducted with the silica particles indicated in Table 1.

TABLE 1

| | Particle |
|---|---|
| | diameter |
| Reference | [nm] |
| SP-1 | 111 |
| SP-2 | 135 |
| SP-3 | 138 |
| SP-4 | 144 |
| SP-5 | 155 |

The indicated particles sizes are the z-average particle sizes as determined by Dynamic Light Scattering (DLS).

### Example 1

5.117 g of sodium aluminate powder were dissolved under agitation in 4650 g of deionized water to obtain a sodium aluminate solution, which was then heated to 50° C. while being agitated.

6081.5 g of silica sol (with 26.26 wt % SiO₂, respective to the total weight of the silica sol) were under agitation heated to 50° C. and then slowly added under agitation over 90 min to the sodium aluminate solution.

The resulting solution was then heated to 70° C., stirred for a further 60 min, and then allowed to cool to room temperature, all the while being agitated, yielding 10646 g of doped silica sol having alkaline pH (with 15 wt % SiO₂, respective to the total weight of the silica sol), thus obtaining the doped silica particles SP-1-D, SP-4-D and SP-5-D, respectively.

### Example 2

6225 g of acidic (pH 2-3) silica sol (with 15 wt % SiO₂, relative to the total weight of the silica sol) were diluted with 4760 g of deionized water to get 10985 g of silica sol (with 8.5 wt % SiO₂, relative to the total weight of the silica sol). To this were then added 31.125 g of Silquest A-1230. The resulting solution was heated to 90° C. while being agitated, and then allowed to cool to room temperature, yielding 10861 g of surface-modified silica sol (with 8.6 wt % SiO₂, relative to the total weight of the silica sol) with the surface modified silica particles SP-5-M.

### Example 3

Surface-modified doped silica particles were produced as described for Example 2, except that the silica sols used were the doped silica sols obtained in Example 1 rendered acidic, thus yielding the surface-modified doped silica sol with the surface modified doped silica particles SP-1-D-M, SP-2-D-M, SP-3-D-M, SP-4-D-M and SP-5-D-M, respectively.

### Example 4

Chemical mechanical polishing was performed with an aqueous composition as indicated in Table 2, with wt % and ppm relative to the total weight of the composition. Before use in chemical mechanical polishing the compositions were filtered (0.3 μm).

TABLE 2

| | Content | |
|---|---|---|
| Silica particles | 2.5 | wt % |
| Malonic acid | 0.0270 | wt % |
| Fe(NO₃)₃ | 0.0075 | wt % |
| Kathon ICP II | 48 | ppm |
| Hydrogen peroxide | 4 | wt % |
| (H₂O₂) | | |

Chemical mechanical polishing was performed on an Mirra® Mesa CMP 200 mm (available from Applied Materials Inc., Santa Clara, CA, USA) using an IC1000™ CMP polishing pad (available from DuPont de Nemours, Wilmington, Delaware, USA) on 8″ TEOS (silicon oxide) and tungsten wafers. Further polishing conditions are indicated in the following Table 3.

TABLE 3

| | |
|---|---|
| Flow rate | 100 ml/min |
| Polishing time | 1 min |
| Dynamic force | 4 psi as down force |
| Platen speed (PS) | 80 rpm |
| Head speed (HS) | 72 rpm |

Results for chemical mechanical polishing were as shown in Table 4 below, wherein PC-1 to PC-3 are comparative examples.

TABLE 4

| | | | | Removal | |
|---|---|---|---|---|---|
| | | | | rate | Removal |
| | | | Zeta | Silicon | rate |
| | | pH at | potential | oxide | Tungsten |
| Ref. | Silica | 20° C. | [mV] | [A/min] | [A/min] |
| PC-1 | SP-1-D | 2.62 | −24 | 103 | 2217 |
| PC-2 | SP-4-D | 2.67 | −34 | 192 | 2890 |
| PC-3 | SP-5-D | 2.61 | −23 | 193 | 2333 |
| P-1 | SP-5-M | 3.18 | −26 | 35 | 2542 |
| P-2 | SP-1-D-M | 2.63 | −23 | 86 | 2201 |
| P-3 | SP-2-D-M * | 2.64 | −28 | 41 | 2495 |
| P-4 | SP-2-D-M * | 2.65 | −24 | 35 | 2460 |
| P-5 | SP-3-D-M | 2.67 | −22 | 48 | 2753 |
| P-6 | SP-4-D-M | 2.66 | −34 | 43 | 2307 |
| P-7 | SP-5-D-M | 2.62 | −23 | 65 | 2375 |

* Two different lots of silica particles.

As is shown by the removal rates for silicon oxide and tungsten, in comparison to the aluminate-doped silica particles of PC-1 to PC-3, the surface-modified silica particles of, for example, P-1 comprising the alkoxy organosilane show improved selectivity by having a high removal rate of tungsten and a significantly reduced removal rate for silicon oxide, at the same time maintaining the high level of removal rate for tungsten.

The data of Table 4 also shows that the combination of doping with aluminate and surface modification with the alkoxy organosilane, see P-2 through P-7, also leads to a reduction in the removal rate for silicon oxide. However, it has surprisingly been found that the compositions used for P-2 through P-7 show significantly improved dispersion stability and can therefore be stored significantly longer than the composition used in P-1.

In general, it has been surprisingly found that the use of an alkoxy organosilane as defined herein leads to a significant improvement in removal rate selectivity between a silicon oxide layer, i.e. a dielectric layer, and a metal or metal alloy layer, particularly a tungsten layer. It has come quite as a surprise that the alkoxy organosilane allows to modify silica particles as used herein in such a way that a high removal rate for metal or metal alloy, particularly tungsten, can be obtained while at the same time allowing for a very low removal rate for silicon oxide, i.e. dielectric materials. The present surface-modified silica particles are therefore believed to be well suited for use in chemical-mechanical polishing of metal and metal alloy layers, particularly of tungsten layers.

1. Modified silica particles comprising an alkoxy organosilane on the surface.

2. Modified silica particles according to claim 1, wherein the silica particles are colloidal silica particles.

3. Modified silica particles according to claim 1, wherein the silica particles are water glass-based.

4. Modified silica particles according to claim 1, wherein the alkoxy organosilane is a hydrophilic alkoxy organosilane.

5. Modified silica particles according to claim 1, wherein the alkoxy silane is a poly(alkoxy) organosilane.

6. Modified silica particles according to claim 1, wherein the alkoxy organosilane is of the following formula (I) 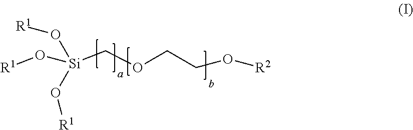
wherein R¹ and R² are at each occurrence independently of each other selected from the group consisting of methyl, ethyl and propyl; a is an integer of at least 1 and at most 5; and b is an integer of at least 1 and at most 20;
wherein preferably R¹ and R² are all methyl, a is 3, and b is 11.

7. Modified silica particles according to claim 1, wherein the silica particles are doped with an alkali metal aluminate.

8. Composition comprising water and the modified silica particles of claim 1, wherein the composition is acidic.

9. Composition according to claim 8, wherein the composition has a pH of at least 1.0 and of at most 5.0, preferably of at least 2.0 and of at most 4.0.

10. Composition according to claim 8, further comprising any one or more of the group consisting of biocide, pH-adjusting agent, pH-buffering agent, oxidizer, chelating agent, corrosion inhibitor, and surfactant.

11. Method for producing the modified silica particles of claim 1, said method comprising the steps of
(a) providing an aqueous dispersion of silica particles;
(b) providing an alkoxy organosilane;
(c) in case said aqueous dispersion not yet being acidic, subsequently rendering the aqueous dispersion of silica particles acidic; and
(d) then bringing the silica particles and the alkoxy organosilane into contact with each other, thereby obtaining the modified silica particles.

12. Method for producing the modified silica particles according to claim 11, wherein following step (a) and before step (c) the silica particles are doped with an aluminate.

13. Method for chemical mechanical polishing comprising the steps of
(A) providing a substrate comprising
(i) at least one layer comprising, preferably essentially consisting of, silicon oxide; and
(ii) at least one layer comprising, preferably essentially consisting of, one or more metal or metal alloy;
(B) providing the composition of claim 8;
(C) providing a chemical mechanical polishing pad with a polishing surface;
(D) bringing the polishing surface of the chemical mechanical polishing pad into contact with the substrate; and
(E) polishing the substrate such that at least a part of the substrate is removed.

14. Method according to claim 13, wherein
(i) the silicon oxide is selected from the group consisting of borophosphosilicate glass (BPSG), plasma-enhanced tetraethyl ortho silicate (PETEOS), thermal oxide, undoped silicate glass, high density plasma (HDP) oxide, and silane oxide; and/or
(ii) the one or more metal or metal alloy is selected from the group consisting of tungsten, tantalum, copper, titanium, titanium nitride, aluminum silicon, and any combination of any of these, and preferably is tungsten.

15. Method according to claim 13, wherein the substrate is selected from the group consisting of flat panel displays, integrated circuits (ICs), memory or rigid disks, metals, interlayer dielectric devices (ILDs), semiconductors, micro-electro-mechanical systems, ferroelectrics, and magnetic heads.
